(19) United States
(12) Patent Application Publication
(10) Pub. No.: US 2008/0289683 A1
(43) Pub. Date: Nov. 27, 2008

(54) Thin-Film Solar Cell Interconnection

(76) Inventors: Timothy Michael Walsh, Victoria (AU); Armin Gerhard Aberle, New South Wales (AU); Stewart Ross Wenham, New South Wales (AU)

Correspondence Address: Husch Blackwell Sanders, LLP;Welsh & Katz, 120 S RIVERSIDE PLAZA, 22ND FLOOR, CHICAGO, IL, 60606, US

(21) Appl. No.: 11/628,387

(22) PCT Filed: May 23, 2005
(86) PCT No.: PCT/AU05/00734

§ 371 Date: Mar. 4, 2008

(30) Foreign Application Priority Data
Jun. 4, 2004 (AU) 2004903028

(51) Int. Cl. H01L 31/00

(52) U.S. Cl. 136/255

(57) ABSTRACT

A method of interconnecting thin-film solar cells formed on a foreign insulating substrate or superstrate is described: the top and bottom layers of the thin-film solar cells having a sheet resistances below 10,000 Ω/sq. The method comprises the steps of forming a thin-film solar cell structure comprising at least an n⁺-type layer (2,3) and a p⁺ type layer (4) on the foreign substrate/superstrate, and forming one or more electrical contacts (19), each contact being between an n⁺ type layer on one portion of the substrate/superstrate to a p⁺-type layer (16) on an adjacent portion of the substrate/superstrate. Each electrical contact (19) is formed, at least in part, from respective materials of the n⁺ type layer (2,3) and the p⁺ type layer (4) of the initially formed solar cell structure: and the materials of the n⁺ type layer (2,3) and the p⁺ type layer (4) forming at least part of each electrical contact are brought into a liquid phase by eg laser a first time and subsequently into a mixed solid phase (16) during the formation of the other side of the electrical contact (19). Deposition of a conductor at the bottom of the groove formed by the laser forms the electrical interconnection (19) between the neighbouring cells.

### FIELD OF INVENTION

The present invention relates broadly to a method of interconnecting thin-film solar cells formed on a foreign insulating substrate or superstrate, and to a thin-film solar cell module.

### BACKGROUND

Thin-film silicon solar cells have the potential to generate solar electricity at much lower cost than is possible with conventional, silicon wafer-based technology. This is due to two factors: Firstly, if deposited onto a textured supporting substrate or superstrate, the amount of silicon semiconductor material in the solar cells can be reduced by more than 99% with little penalty in the cell's energy conversion efficiency; Secondly, thin-film solar cells can be manufactured on large-area substrates (˜1 m²), streamlining the production process and further reducing processing costs.

Whilst the output current of a solar cell scales with device size, the output voltage does not, and hence large-area (˜1 m²) solar cells have a very high current but a low voltage. The large current (>200 A) causes excessive ohmic losses, which give rise to a low energy conversion efficiency. This problem is overcome in thin-film photovoltaic modules by dividing the large-area solar cell into many (>100) smaller cells, each having the same size, and electrically interconnecting them in series, so that their voltages add and their current is less than 1% of the current of the large-area cell.

The standard method in industry for forming interconnected thin-film silicon solar cells involves three separate laser scribing sets, each preceded by the deposition of a thin material layer (first a transparent conductive oxide (TCO), then the thin-film semiconductor solar cell, then another TCO film). This is a complex and rather costly process, given that each TCO film is about as expensive as the semiconductor thin film.

If the top and bottom semiconductor layers both have a sufficiently good lateral electrical conductance, then the use of the TCOs can be avoided and instead the solar cell can be directly contacted. Different schemes have been proposed to design interconnect structures for such thin-film solar cells.

In WO 03/019674 A1, a chain linked metal interconnect structure is disclosed in which a conductive layer applied over the entire thin-film solar cell structure is scribed into a series of strips, which are subsequently divided into individual links by scribing transversely to the first scribe direction. The conductive layer contacts the p-type layer and the n-type layer via respective series of point contacts, one series directly onto the top layer of the thin-film solar cell structure, and another series through the entire thin-film solar cell structure to the bottom layer. Another scheme is described in U.S. Pat. No. 5,595,607. This scheme is based on grooves whose side walls are heavily doped in a particular process sequence and subsequent filling of the grooves with metal.

The present invention seeks to provide an alternative method for directly contacting the semiconductor in thin-film solar cells which have top and bottom semiconductor layers with sufficiently good lateral electrical conductance and which are formed on a foreign insulating substrate or superstrate.

### SUMMARY

In accordance with a first aspect of the present invention there is provided a method of interconnecting thin-film solar cells formed on a foreign insulating substrate or superstrate, the top and bottom layers of the thin-film solar cells having sheet resistances below 10,000 Ω/sq, the method comprising the steps of forming a thin-film solar cell structure comprising at least an n⁺-type layer and a p⁺-type layer on the foreign substrate/superstrate, and forming one or more electrical contacts, each contact being between an n⁺-type layer on one portion of the substrate/superstrate to a p⁺-type layer on an adjacent portion of the substrate/superstrate, wherein each electrical contact is formed, at least in part, from respective materials of the n⁺-type layer and the p⁺-type layer of the initially formed solar cell structure; and wherein the materials of the n⁺-type layer and the p⁺-type layer forming at least part of each electrical contact are brought into a liquid phase and subsequently into a solid phase during the formation of the electrical contact.

The method may comprise bringing first portions of the thin-film solar cell into a liquid phase and subsequently into a solid phase, thereby forming one or more heavily doped first-type polarity regions extending across the entire thickness of the solar cell structure, bringing second portions of the thin-film solar cell into a liquid phase and subsequently into a solid phase, thereby forming one or more heavily doped second-type polarity regions that extend across the entire thickness of the solar cell structure and that are located adjacent to the respective heavily doped first-type polarity regions; wherein respective pairs of the adjacent re-solidified p⁺-type regions and n⁺-type regions are a component of the ohmic electrical contact between neighboring solar cells.

The excess dopant atoms required to make the p⁺-type and n⁺-type regions forming part of the electrical contact between neighboring solar cells may be provided by a spin-on dopant source.

The excess dopant atoms required to make the p⁺-type and n⁺-type regions forming part of the electrical contact between neighboring solar cells may be provided by a gas dopant source.

The re-solidified n⁺-type and p⁺-type regions may be in intimate physical contact with one another, and electrical contact between neighboring solar cells is established by a tunnel recombination p-n junction thus formed.

The excess dopant atoms required to make the p⁺-type and n⁺-type regions forming the electrical contact between neighboring solar cells may be provided by a spin-on dopant source.

The excess dopant atoms required to make the p⁺-type and n⁺-type regions forming the electrical contact between neighboring solar cells may be provided by a gas dopant source.

An electrically conducting material may be locally formed on the exposed surface of the re-solidified n⁺-type and p⁺-type regions.

The method may comprise the steps of forming an overlayer on the solar cell and locally diffusing elements from this overlayer into the tunnel recombination junction by means of a laser treatment, and removing the overlayer.

The semiconductor material forming the solar cell may be silicon and the overlayer film on the solar cell may be titanium dioxide.

The method may comprise the steps of forming one or more grooves in the solar cell structure such that at least a surface region of one side wall of each groove has an n⁺-type polarity and at least a surface region of the other side wall of the groove has a p⁺-type polarity; and forming an electrical contact layer in each groove such that the respective surface regions of the side walls are in electrical contact with one another.

The substrate/superstrate may be transparent and the step of forming the electrical contact layer over each groove may comprise depositing a positive photoresist over the solar cell structure including over each groove; directing a light beam towards the solar cell structure through the transparent substrate/superstrate such that substantially only portions of the photoresist deposited between the side walls of the respective grooves are exposed to the light beam; removing the portions of the photoresist exposed to the light beam; depositing a conducting layer onto the solar cell structure such that at least portions of the respective side walls of each groove are in electrical contact with one another, and removing the photoresist and the conducting overlayer on the photoresist.

A wavelength of the light beam may be chosen such that the light beam is absorbed in the solar cell structure.

The solar cell structure may be silicon based, and the light beam may be a UV light beam.

The excess dopant atoms required for the formation of the n⁺-type and p⁺-type portions of the electrical contact may be provided by a spin-on dopant source.

The excess dopant atoms required for the formation of the n⁺-type and p⁺-type portions of the electrical contact may be provided by a gas dopant source. The method may comprise the steps of forming a first dielectric layer containing n⁺-type or p⁺-type dopant atoms on the solar cell structure; forming one or more first grooves through the dielectric layer and the entire thickness of the solar cell structure such that side walls of each groove exhibit n⁺-type or p⁺-type doping based on the type of the dopant atoms of the first dielectric layer; removing the first dielectric layer; depositing a second dielectric layer that does not contain n-type or p-type dopant atoms; forming one or more second grooves through the second dielectric layer and the entire thickness of the solar cell structure adjacent to respective first grooves such that one side wall of each first groove is removed and a new side wall is made forming a widened groove; doping at least a surface region of each new side wall with a polarity opposite to the type of the dopant atoms of the first dielectric layer; removing the second dielectric layer; and forming the electrical contact layer over each widened groove such that at least portions of the surface regions of the side walls of the widened groove are in electrical contact with one another.

The solar cell structure may comprise at least a bottom layer and a top layer of opposite polarity and the bottom layer exhibits a dopant dose that is at least two times higher than the dopant dose of the top layer, the method comprising the steps of forming one or more first grooves through the entire thickness of the solar cell structure such that side walls of each groove exhibit n⁺-type or p⁺-type doping based on the type of the dopant atoms of the bottom layer; depositing a dielectric barrier layer that does not contain n-type or p-type dopant atoms; forming one or more second grooves through the barrier layer and the entire thickness of the solar cell structure adjacent to respective ones of the first grooves such that one side wall of each first groove is removed and a new side wall is formed to form a widened groove; doping at least a surface region of each new side wall with a polarity opposite to the type of the dopant atoms of the bottom layer; removing the dielectric barrier layer; and forming the electrical contact layer over each widened groove such that at least portions of the surface regions of the side walls of the widened groove are in electrical contact with one another.

In accordance with a second aspect of the present invention there is provided a thin-film solar cell module having top and bottom layers with sheet resistances below 10,000 Ω/sq, the module comprising a thin-film solar cell structure formed on a foreign insulating substrate or superstrate and comprising at least an n⁺-type layer and a p⁺-type layer, and one or more electrical contacts, each contact being between an n⁺-type layer on one portion of the substrate/superstrate to a p⁺-type layer on an adjacent portion of the substrate/superstrate, wherein each electrical contact is formed, at least in part, from respective materials of the n⁺-type layer and the p⁺-type layer; and wherein the materials of the n⁺-type layer and the p⁺-type layer forming part of each electrical contact have undergone a transition into a liquid phase and subsequently into a solid phase during the formation of the electrical contact.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIGS. 1 to 9 are schematic cross-sectional drawings illustrating a method of interconnecting thin-film solar cells formed on a foreign substrate, in accordance with an embodiment of the present invention.

FIG. 10 shows a Focused Ion Beam (FIB) image of one side of a single interconnect made according to the embodiment of FIGS. 1 to 9.

FIG. 11 shows an optical micrograph of an interconnect made according to the embodiment of FIGS. 1 to 9.

FIG. 12 shows an optical micrograph of a completed interconnect made according to the embodiment of FIGS. 1 to 9.

FIG. 13 shows a schematic cross-sectional drawing of a sample in another embodiment of the present invention, just prior to the interconnection of the two adjacent side walls in the figure by a metal film using the method corresponding to FIGS. 6 to 9.

FIGS. 14 and 15 are schematic cross-sectional drawings illustrating a method of interconnecting thin-film solar cells formed on a foreign substrate, in accordance with another embodiment of the present invention.

### DETAILED DESCRIPTION

One embodiment of the invention will now be described which has demonstrated an ability to produce monolithically interconnected p⁺nn⁺ thin-film crystalline silicon solar cells on planar glass (cell structure=glass/n⁺np⁺). However, while the process is described for a p⁺nn⁺ crystalline silicon diode on a glass substrate, it will be appreciated that the process is also applicable to other diode structures, including of the type n⁺πp⁺, whereby π stands for a layer of p (positive), n (negative) or i (intrinsic) type semiconductor material, other semiconductor materials, textured and/or barrier-coated glass, or other foreign insulating substrates. It is noted that all embodiments of the present invention rely on the lateral conductance of current within the semiconductor. A well suited semiconductor is crystalline silicon, but any semiconductor which can achieve doped layers with sheet resistances below 10,000 Ω/sq. is suitable.

The process in the first example embodiment applies to a solar cell structure where the dopant dose in the bottom n⁺ layer exceeds that of the p⁺ layer by a factor of two or more. However, it will be appreciated that the process can also be equally used for other diode structures with different dopant densities in the individual layers, and some example modifications of the process of the example embodiment to suit such structures will also be described below.

It should be noted that all the schematic figures are not to scale—for the sake of clarity, the vertical direction has been strongly increased with respect to the horizontal direction.

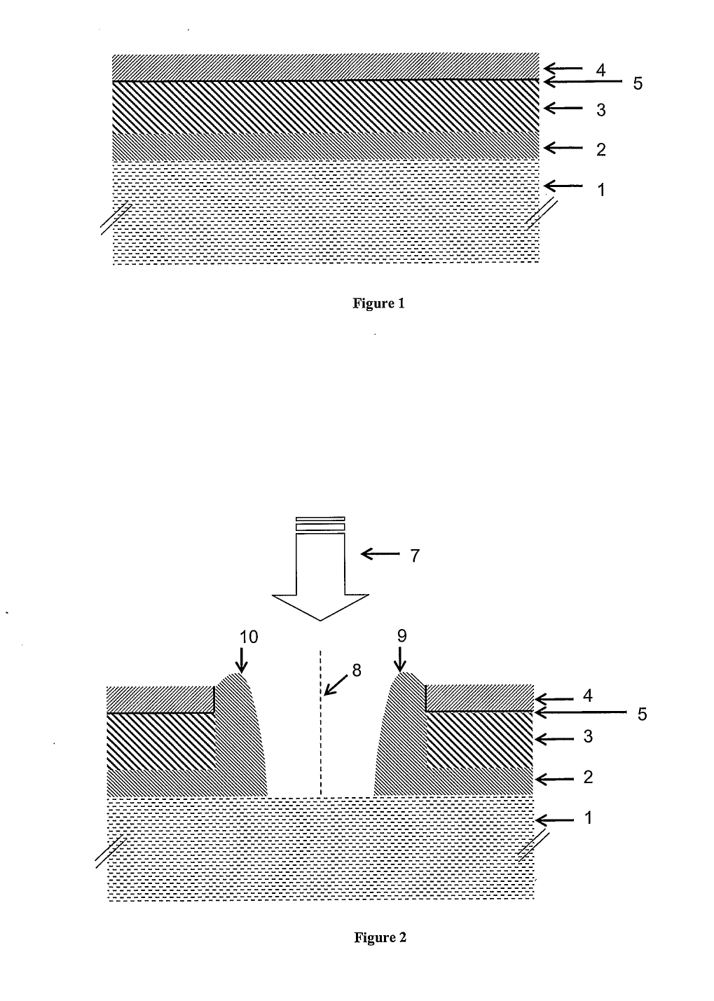

Referring to FIG. 1, the solar cell consists of a glass substrate (1) with three semiconductor layers (2, 3 and 4), whereby a lightly doped n-type absorber region (3) is sandwiched between two heavily doped layers (2 and 4). Layer (4) is p⁺-type and thus, in addition to creating the required p-n junction, enables the formation of a low-resistance ohmic contact on its surface. For the same reason, layer (2) is n⁺-type. The fabrication of the p⁺nn⁺ crystalline silicon thin-film solar cell on glass can be performed with known fabrication techniques. For instance solid phase crystallisation (SPC) of amorphous silicon at temperatures around 600° C. can be used, as shown by Matsuyama et al. (High-quality polycrystalline silicon thin film prepared by a solid phase crystallisation method, Journal of Non-Crystalline Solids 198-200, pp. 940-944, 1996).

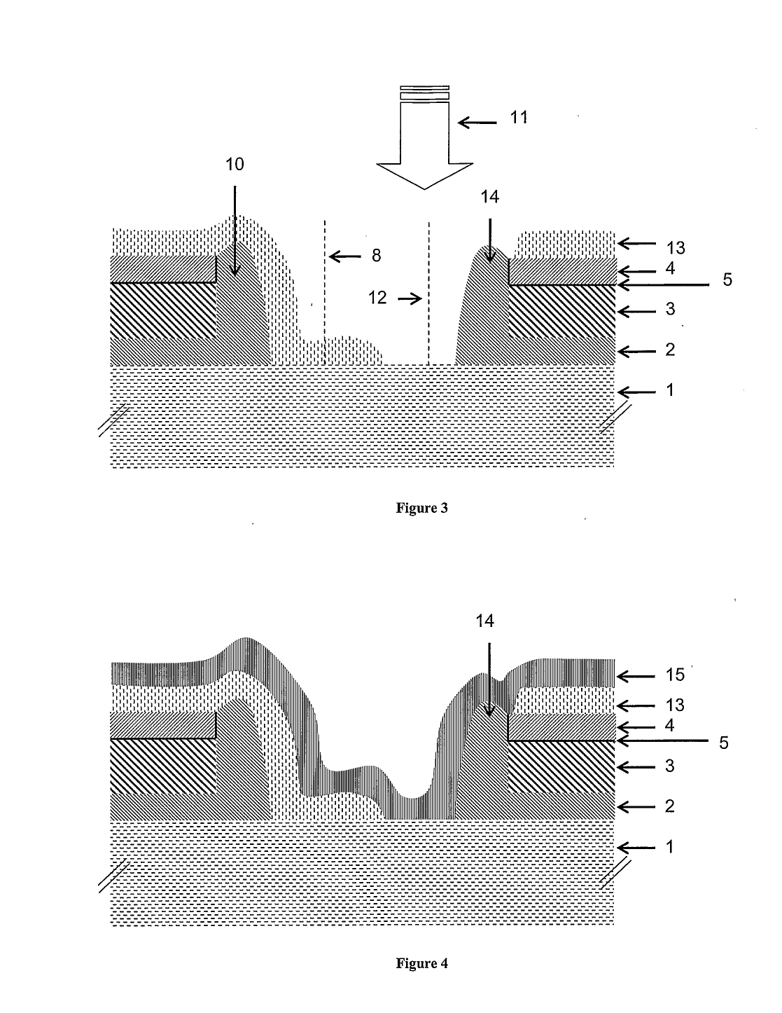

Next, as seen in FIG. 2, a groove is formed through the three silicon layers (2, 3 and 4) using a laser beam (7). The laser beam (7) in the example embodiment is pulsed, has a wavelength of 1064 nm, and comes from a Nd:YAG laser. The pulse duration is about 1-2 ns, the pulse frequency (i.e., the repetition rate, or Q-switch frequency) is in the range of 10-50 kHz, and the beam is approximately of circular cross section with a Gaussian profile and a diameter of 5-30 μm. It has been recognized that when a laser pulse (7) hits the sample, it heats the silicon layers (2, 3 and 4) locally, causing them to ablate (or vaporize) near the middle of the stripe (8) and to melt and then recrystallise near the edges (9, 10) of the stripe. During the liquid phase, dopant atoms from silicon layers (2, 3 and 4) are mixed together. The most abundant dopant species will determine the final dopant type of the recrystallised silicon. Because the n-type dopant dose in the n⁺ layer (2) exceeds the n-type and p-type dopant doses in the other silicon layers (3 and 4) in the example embodiment, the recrystallised silicon side-walls (9) and (10) in FIG. 2 will both be moderately to heavily n-type doped.

It is noted that the process may be modified for solar cells having a bottom-layer dopant dose that is not significantly higher than the top-layer dopant dose. In such a modification, a dielectric film containing the desired bottom-layer-type dopant atoms is initially deposited onto the surface of the top layer (4). During the subsequent formation of the groove, this will result in the prominence of the bottom-layer-type dopant dose in the side walls (9 and 10). After formation of the groove, the dielectric film is removed. Alternatively, the source of dopants may be a gas source instead of a spin-on dopant layer.

By adding an additional processing sequence into the above modified process, the power output of the fabricated PV string can be increased due to reduced parasitic losses associated with the heavily doped p-n junction regions (“n⁺-p⁺ junctions”). The aim of the additional processing sequence is to introduce, by etching of the semiconductor, a gap between the heavily doped top layer of each solar cell and the heavily doped, recrystallised, opposite-polarity groove wall. This further modified method comprises the following steps:
depositing the dielectric film containing bottom-layer-type dopant atoms onto the surface of the large-area thin-film solar cell on glass;
forming the grooves through the dielectric film and the entire semiconductor film by means of laser scribing, whereby the side walls of the grooves are heavily doped with bottom-layer-type dopant atoms. Because the dielectric film is less heat resistant than the semiconductor material, the gap in the dielectric will be significantly wider than the gap in the semiconductor film. The dielectric thus acts as a self-aligned mask;
submitting the semiconductor to a semiconductor etch process and removing a semiconductor thickness that corresponds approximately to the thickness of the heavily doped top layer. The bottom-layer dopant type wall is much thicker than the heavily doped top layer and hence is, in relative terms, negligibly thinned; and
removing the dielectric layer.

Returning now to FIG. 2, it should also be noted that the height of the recrystallised side-walls (9) and (10) is greater than the combined thickness of silicon layers (2, 3 and 4). The reason for this is believed to be the thermal shock wave associated with the absorbed laser energy, causing a lateral, outward-directed (with respect to the centre of the laser beam) flow of the molten silicon material. During this lateral outward flow the molten material cools down and eventually recrystallises once the temperature has fallen below silicon's melting point. The resulting structure thus appears like a “frozen wave”.

By moving the substrate (1) along a straight line (which defines, for example, the y axis) with respect to the laser beam, and with the speed chosen such that the circular laser-treated region of the jth pulse overlaps significantly (˜70-90%) with the region of pulse j−1, a linear groove can be formed in the silicon film in the example embodiment. For the fabrication of an array of parallel grooves, the sample is moved a certain distance along the x-axis before scribing of the next groove is commenced. The method in the example embodiment uses a computer-controlled x-y stage (not shown) attached to the laser station.

After the first set of grooves has been formed (at a suitable distance apart which is determined by the trade-off between the losses due to the lateral conductance of the film and the losses associated with the “dead”, or inactive area associated with the grooves), the next step is to deposit a layer which will act as a dopant diffusion barrier. One example of such a diffusion barrier is a layer of silicon nitride (SiN) (with thickness 30-100 nm) deposited by plasma-enhanced chemical vapour deposition (PECVD). Another such example of a diffusion barrier is a layer of undoped spin-on glass (SOG).

The sample is then put back onto the x-y stage of the laser station and aligned such that its position mimics as closely as possible (accuracy approximately ±5 μm in the example embodiment) its position during the first laser processing step. The x-y table is then shifted along the x-axis by a distance that corresponds to half the width of one of the existing grooves. Then, a similar laser process as that described with reference to FIG. 2 is performed. Due to the lateral displacement of half a groove width, the right-hand wall (9) from the first groove (8) along with the dielectric diffusion barrier layer (13) is ablated (i.e., removed), see FIG. 3.

In the example embodiment, the material near the center of the laser beam (11) is ablated, that is removed by vaporization, due to the large amount of energy from the laser beam (11) that the film absorbs. It can be assumed that the laser beam (11) has an approximately Gaussian energy density profile in cross-section, so that near the center of the laser beam (11) a large amount of energy is absorbed, but near the edges of the lesser beam (11) a lesser amount of energy is absorbed. As a result, while the material at the center of the laser beam (11) is heated to the point of vaporization, the material at the edges is merely melted. It is the expansion of the ablating, vaporized material that “pushes” the molten material at the edges of the laser beam (11) aside to form the “frozen wave” mentioned above.

Next, a dielectric film (15) containing p-type dopant atoms is applied, as shown in FIG. 4. The layer (15) is sufficiently thick to ensure that the silicon film and the grooves are covered. The “doped” layer (15) is a “spin-on glass” in the example embodiment, i.e. a silicon dioxide film containing dopant atoms, which is deposited in liquid form onto the sample's surface by means of a spinner (i.e. a rotating platform, not shown) and then solidified by thermal annealing (“baking”) at moderate temperature.

The whole structure is then subjected to a rapid thermal process (RTP) where the temperature is increased to ˜900° C. for a short period of time (1-30 minutes), so that the dopant species present in the spin-on dopant layer (15) are thermally diffused into the exposed right hand side-wall (14) of the groove in the silicon film. The distance that the dopant atoms are diffused into the silicon side-wall can be controlled by adjusting the annealing time and/or temperature.

Next the spin-on dopant layer (15) and diffusion barrier layer (13) are removed by etching in a suitable acid solution (for example hydrofluoric acid (HF) and/or phosphoric acid (H₃PO₄)). The structure at this point in the process is as shown in FIG. 5, where the left-hand side-wall (10) is doped n-type and is in ohmic electrical contact with the buried n-type layers (2, 3) of the cell to the left of the groove, and the right-hand side-wall (14) is doped p-type on its surface (16) and is in ohmic electrical contact with the top p-type layer (4) of the cell to the right of the groove. In FIG. 5, the diffusion distance is shown to be similar to the thickness of the p⁺ top layer (4).

Alternatively, instead of applying the doped dielectric layer (15), the sample can be subjected to a conventional p-type diffusion process using a high-temperature furnace and a suitable dopant gas atmosphere. The distance that the dopant atoms are diffused into the silicon side-wall can be controlled by adjusting the annealing time and/or temperature. The sample is then cleaned in a suitable etching solution (for instance HF), giving the structure of FIG. 5.

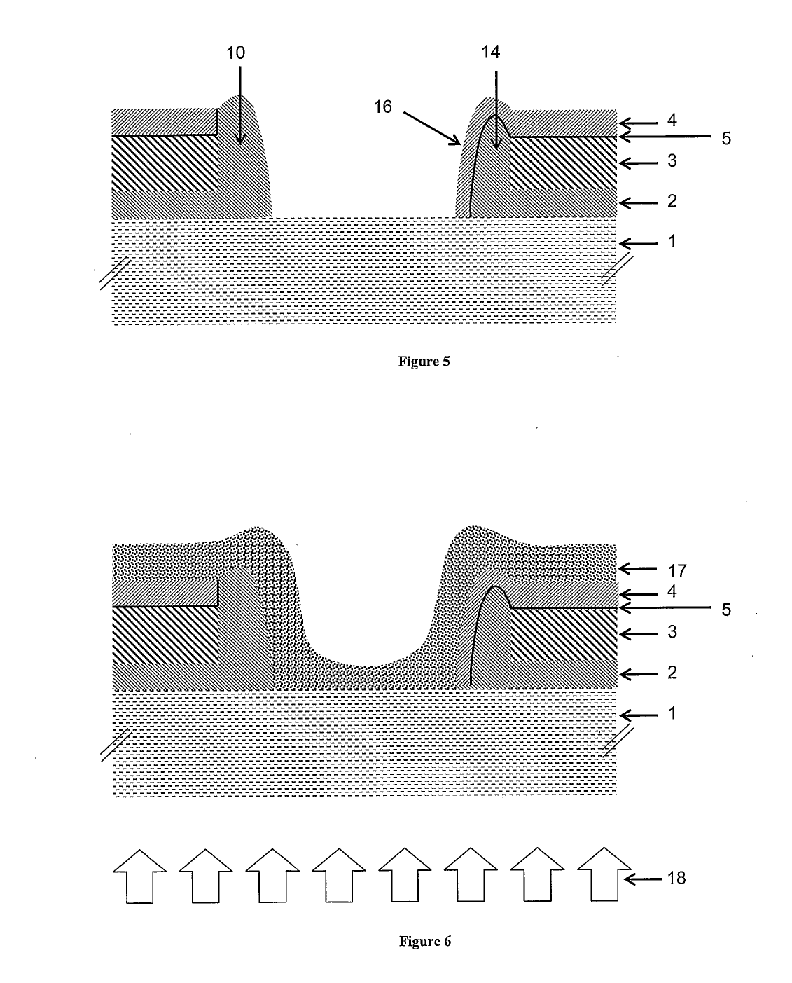

Next, as seen in FIG. 6, a layer of “positive” photoresist (17) is deposited (by spinning in the example embodiment) onto the silicon side of the solar cell. The photoresist layer (17) is sufficiently thick to ensure that the silicon and the grooves are adequately covered. Next, the photoresist layer (17) is exposed to UV light (18) through the glass (1), utilising the silicon layers (2, 3, 4, 10, 14 and 16) as a natural, self-aligned UV mask. Note that crystalline silicon has a very high absorption coefficient α. For UV light α_{Si} is about 10⁸ m⁻¹, and therefore UV light does not penetrate through silicon films that are thicker than 50 nm. The silicon layers used in the example embodiment are thicker than 50 nm, hence the silicon acts as an excellent self-aligned mask against UV exposure of the photoresist covering the silicon.

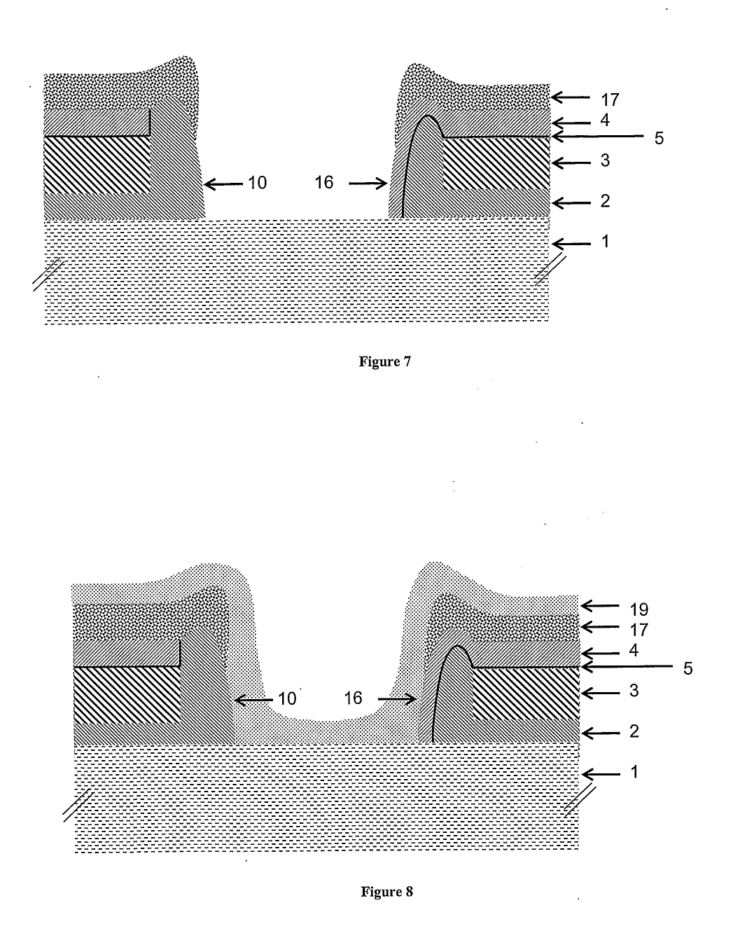

Referring to FIG. 7, the photoresist layer is then developed, removing the areas of photoresist that have been exposed to UV light, so that the silicon layer (4) and the upper parts of the doped side walls (10) and (16) are covered by photoresist (17), and the exposed substrate in the groove and the lower parts of the doped side walls (10) and (16) are free from photoresist.

Referring to FIG. 8, a thin (100-1000 nm) layer (19) of conductive material (aluminium in the example embodiment) is then deposited by evaporation or sputtering over the entire top surface of the device. The metal makes intimate contact with the glass substrate (1) in the groove, and with the exposed portions of the p⁺-type and n⁺-type side walls (10 and 16) of the solar cells on either side of the groove.

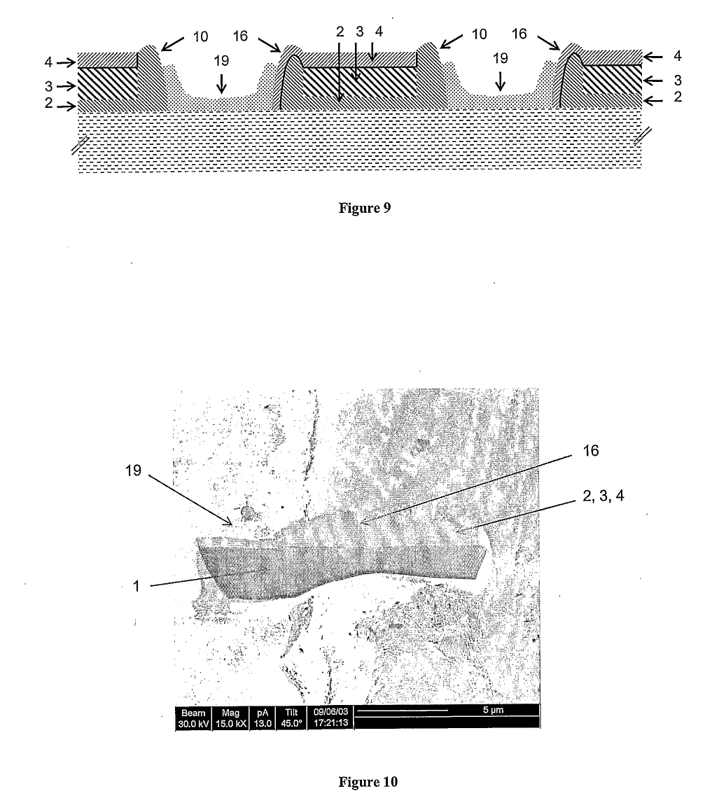

The photoresist (17) is then dissolved chemically, whereby the metal (19) on top of the photoresist is lifted off, leaving metal only in the groove. The sample is then rinsed in water. The final structure is shown in FIG. 9. The metal (19) forms an electrical connection between the n⁺-type wall (10) on the left side of the groove (which is in ohmic electrical contact with the n⁺-type layer (2) of the corresponding solar cell) and the p⁺-type side wall (16) on the right side of the groove (which is in ohmic electrical contact with the p⁺-type layer (4) of the corresponding solar cell). The entire structure now consists of k individual solar cells on the same glass substrate (1), which are electrically interconnected in series.

Whilst this embodiment of the invention has been described in detail up to this point, it will be appreciated that there may be other ways of achieving a structure with these properties, by slightly varying the process sequence as described without departing from the spirit or scope of the present invention.

Using the process described in the above example embodiment, a prototype PV module has been fabricated from a n⁺pp⁺ thin-film crystalline silicon solar cell on a glass substrate (size=50 mm×50 mm). The PV module has twenty individual solar cells electrically connected in series. The open-circuit voltage (V_{OC}) of nineteen of the individual cells was measured under a solar simulator (light intensity corresponding to midday sun on a clear summer day), as was the V_{OC} across the whole module. (Due to the geometry of the sample, the end cell in the string cannot be measured.) The V_{OC} measured across the whole nineteen cells is equal to the sum of the V_{OC}'s of the cells when measured individually. This confirms that the string of solar cells has been successfully interconnected.

Another prototype PV module has been examined using focused ion beam (FIB) microscopy, see FIG. 10. Before the picture of FIG. 10 was taken, a rectangular, approximately 20 μm long trench was milled into the sample (using a focused beam of gallium ions), revealing the cross-sectional shape of the sample. The location of the trench was selected such that the trench runs through the right wall region of a groove. For the FIB image of FIG. 10, the sample was tilted by 45° with respect to the primary Ga ion beam. The FIB image shows, in cross section, the thin-film crystalline Si diode structure (2, 3, 4), the melted and recrystallised silicon region (16) at the edge of the groove, and the metal (19) sitting on the glass substrate (1) in the groove and rising up onto the heavily doped region (16), making electrical contact with it.

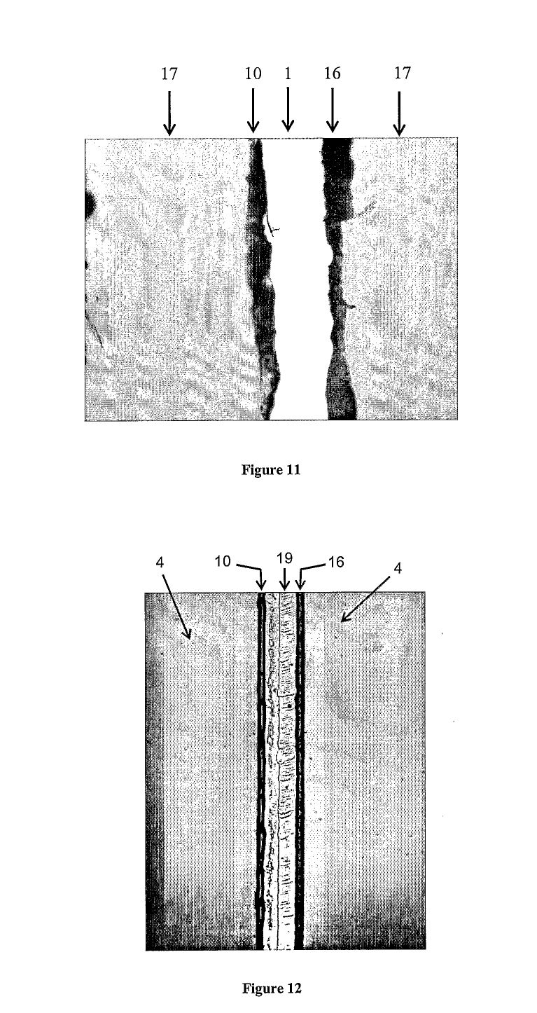

Prototype PV modules were also examined under an optical microscope at different stages during the fabrication process. FIG. 11 shows a transmission-mode optical micrograph of a groove after the photoresist was removed from the groove. It can be seen that the photoresist (17) completely covers the silicon film (2, 3 and 4) including the raised, recrystallised doped areas at the sides of the groove (10 and 16), while the glass substrate (1) in the groove is totally free from photoresist.

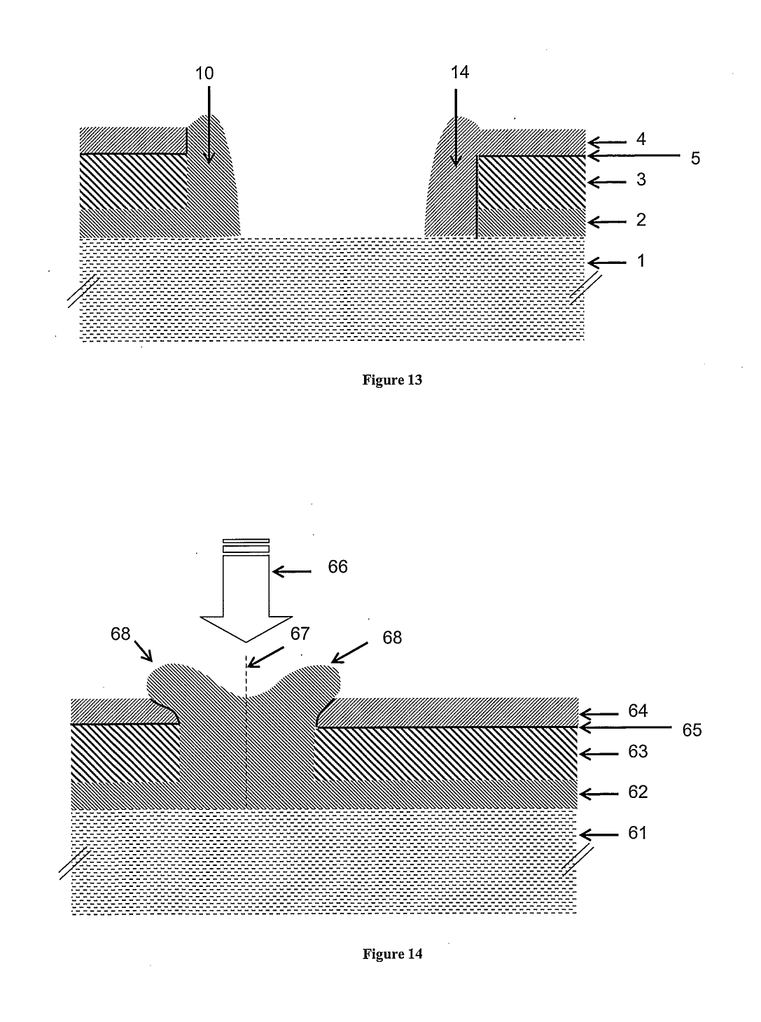

FIG. 12 shows a reflectance-mode optical micrograph of a completed interconnect structure. Three distinct regions are clearly visible: the unaffected silicon film (4), the darker, raised recrystallised doped regions at the edges of the groove (10 and 16), and the metal filling the groove (19). In FIG. 12 the total width of the feature is approximately 60 μm.

Another example embodiment will now be described which relates to FIGS. 1, 2, and 13. Starting point for this embodiment is the situation realized in FIG. 2, which shows a groove formed by laser treatment, whereby both side walls have a bottom-layer-type polarity. Next, a layer of top-layer-type spin-on dopant is applied to the semiconductor surface (not shown), and a second laser groove formed adjacent to the first, such that one side wall of the first type groove is removed, and the new side wall of the widened groove so formed ((14) in FIG. 13) is doped with a polarity corresponding to the top layer (4). Alternatively, the source of dopants may be a gas source instead of a spin-on dopant layer. The resulting structure is shown in FIG. 13. Interconnection of the two adjacent side walls in FIG. 13 by a metal film is realized using the method corresponding to FIGS. 6 to 9.

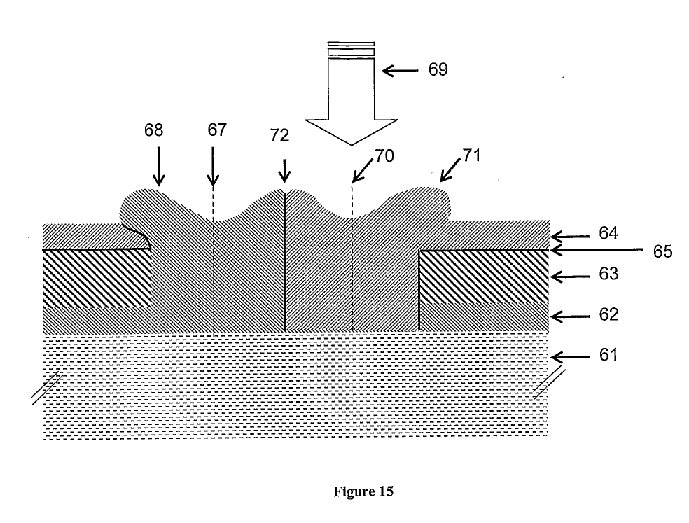

Another example embodiment will now be described with reference to FIGS. 14 and 15. FIG. 14 illustrates a partially completed interconnect in this example embodiment. (61) is the foreign insulating substrate (or superstrate), on which the semiconductor n⁺πp⁺ (or p⁺πn⁺) solar cell (62, 63, 64) is formed. The thick black line (65) indicates the location of the p-n junction. Note that the p-n junction of the initial solar cell could equally well be located between layers (62) and (63). (66) shows the location of a laser beam for formation of a first set of lines, whereby the doping polarity in these lines corresponds to that of the bottom layer (62). (67) is the centre of the laser beam, and (68) is the melted and re-crystallised bottom-layer-type semiconductor region. The laser used in the example embodiment to melt through the semiconductor films (62, 63, 64) is chosen depending on the material from which the various layers are made. For the case of a crystalline silicon semiconductor solar cell, the laser used in the example embodiment is frequency-doubled Nd:YAG laser operating at 532 nm. Note that the laser beam power is adjusted such that it is not sufficient to ablate (i.e., remove) the semiconductor material but merely to melt it.

In the formation of the first set of bottom-layer-type lines (68), a dielectric film containing bottom-layer-type dopant atoms may initially be deposited onto the surface of the top layer (64). This modification is preferred for solar cells having a bottom-layer dopant dose that is not significantly higher than the top-layer dopant dose. The dielectric film in the modification will then be cured by e.g. RTP, such that it will not ablate when the solar cell is laser treated. Alternatively, the dielectric film may be left “wet”. Next, the set of parallel bottom-layer-type lines (68) are formed by means of the laser processing. Then, the dielectric film is removed in that modified process. Alternatively the dopants required to make the first-type stripe may be provided by a gaseous source.

FIG. 15 illustrates the completed interconnect in this example embodiment. The arrow (69) indicates a second laser beam, which is aligned such that its centre (70) is slightly offset from the centre of the first laser beam (67). The offset between the two laser beams is made such that the bottom-layer-type melted and recrystallised stripe (68) meets with the top-layer-type melted and recrystallised stripe (71). The junction (72) between the top-layer-type and bottom-layer-type stripes (71, 68) is a tunnel recombination p-n junction which has almost ohmic behavior. To further improve the ohmic behavior of the tunnel recombination junction, it may be necessary to deposit a suitable film onto the solar cell (for instance a titanium dioxide film in the case of silicon solar cells), to locally diffuse elements from the overlayer into the tunnel recombination junction by means of a laser treatment, and then to remove the overlayer.

In the formation of the top-layer-type stripe (71), a dielectric layer containing top-layer-type dopant atoms may be deposited onto the surface of the solar cell (64). This modification is preferred for solar cells having a top-layer dopant dose that is not significantly higher than the bottom-layer dopant dose. In such a modified process, the dielectric film is then cured by e.g. RTP, such that it will not ablate when the solar cell is laser treated. Alternatively, the dielectric films may be left “wet”. After the laser treatment to form the top-layer-type stripe (71), the dielectric film is removed in the modified process.

It is noted that in such a modified process, the semiconductor region which is left exposed after the second set of laser processes (i.e. the region above the top-layer-type stripe (71)) may be metallised by e.g. electroplating to form an ohmic contact between the p-type stripe (71) and the n-type stripe (68).

Alternatively the dopants required to make the second-type stripe may be provided by a gaseous source.

In another example embodiment, the process may be differently modified for solar cells having a bottom-layer dopant dose that is very similar to the top-layer dopant dose. In such an example embodiment, the extra dopant species required can be provided through utilising a gas immersion laser doping (GILD) system to fabricate the laser treated regions, the gas containing atomic species which produce either n-type or p-type doping.

The solar cells created in accordance with embodiments of the present invention are typically of rectangular shape, with a length/corresponding approximately to the length of the glass substrate (typically 50-120 cm in the PV industry) and a width w of about 1-3 mm. This (narrow) width is chosen because, under outdoor illumination, it represents the optimum trade-off between resistive losses due to lateral current flow in the doped layers of the solar cells and parasitic losses associated with the edge regions of the solar cells. For a large-area glass substrate (width ˜100 cm), this means that there are 300-1000 individual solar cells electrically interconnected in series, forming a single PV module.

Due to the large number of solar cells, the voltage between the two end terminals of the PV module can reach up to 1000 Volts. This can cause safety hazards and should be avoided for particular applications. This can easily be accomplished in different embodiments of the invention, by adding “finger” lines to the contact lines whereby the finger lines branch off perpendicularly from the contact lines. The result is a comb-like structure for both types of electrodes on each cell, whereby the fingers of the first comb-like structure are interdigitated with the fingers of the second comb-like structure. The parallel fingers of each comb are joined by an interconnecting “busbar”. The busbar is the side wall of the contact line with the same polarity as the finger. Interconnection of neighboring cells is achieved by either the metal in the grooves (whereby the n-type busbar of one cell is connected with the p-type busbar of the cell across the groove) or, for the embodiment shown in FIG. 15, the tunnel recombination p-n junction.

It will be appreciated by a person skilled in the art that numerous variations and/or modifications may be made to the present invention as shown in the specific embodiments without departing from the spirit or scope of the invention as broadly described. The present embodiments are, therefore, to be considered in all respect to be illustrative and not restrictive.

1. A method of interconnecting thin-film solar cells formed on a foreign insulating substrate or superstrate, the top and bottom layers of the thin-film solar cells having sheet resistances below 10,000 Ω/sq, the method comprising the steps of
forming a thin-film solar cell structure comprising at least an n⁺-type layer and a p⁺-type layer on the foreign substrate/superstrate, and
forming one or more electrical contacts, each contact being between an n⁺-type layer on one portion of the substrate/superstrate to a p⁺-type layer on an adjacent portion of the substrate/superstrate,
wherein each electrical contact is formed, at least in part, from respective materials of the n⁺-type layer and the p⁺-type layer of the initially formed solar cell structure; and
wherein the materials of the n⁺-type layer and the p⁺-type layer forming at least part of each electrical contact are brought into a liquid phase and subsequently into a solid phase during the formation of the electrical contact.

2. The method as claimed in claim 1, wherein the method comprises
bringing first portions of the thin-film solar cell into a liquid phase and subsequently into a solid phase, thereby forming one or more heavily doped first-type polarity regions extending across the entire thickness of the solar cell structure,
bringing second portions of the thin-film solar cell into a liquid phase and subsequently into a solid phase, thereby forming one or more heavily doped second-type polarity regions that extend across the entire thickness of the solar cell structure and that are located adjacent to the respective heavily doped first-type polarity regions;
wherein respective pairs of the adjacent re-solidified p⁺-type regions and n⁺-type regions are a component of the ohmic electrical contact between neighboring solar cells.

3. The method as claimed in claim 2, wherein the re-solidified n⁺-type and p⁺-type regions are in intimate physical contact with one another, and electrical contact between neighboring solar cells is established by a tunnel recombination p-n junction thus formed.

4. The method as claimed in claim 3, wherein an electrically conducting material is locally formed on the exposed surface of the re-solidified n⁺-type and p⁺-type regions.

5. The method as claimed in claim 3, comprising the steps of forming an overlayer on the solar cell and locally diffusing elements from this overlayer into the tunnel recombination junction by means of a laser treatment, and removing the overlayer.

6. The method as claimed in claim 5, wherein the semiconductor material forming the solar cell is silicon and the overlayer film on the solar cell is titanium dioxide.

7. The method as claimed in claim 2, wherein the excess dopant atoms required to make the p⁺-type and n⁺-type regions forming part of the electrical contact between neighboring solar cells are provided by a spin-on dopant source.

8. The method as claimed in claim 2, wherein the excess dopant atoms required to make the p⁺-type and n⁺-type regions forming part of the electrical contact between neighboring solar cells are provided by a gas dopant source.

9. The method as claimed in claim 3, wherein the excess dopant atoms required to make the p⁺-type and n⁺-type regions forming the electrical contact between neighboring solar cells are provided by a spin-on dopant source.

10. The method as claimed in claim 3, wherein the excess dopant atoms required to make the p⁺-type and n⁺-type regions forming the electrical contact between neighboring solar cells are provided by a gas dopant source.

11. The method as claimed in claim 1, comprising the steps of
forming one or more grooves in the solar cell structure such that at least a surface region of one side wall of each groove has an n⁺-type polarity and at least a surface region of the other side wall of the groove has a p⁺-type polarity; and
forming an electrical contact layer in each groove such that the respective surface regions of the side walls are in electrical contact with one another.

12. The method as claimed in claim 11, wherein the substrate/superstrate is transparent and the step of forming the electrical contact layer over each groove comprises;
depositing a positive photoresist over the solar cell structure including over each groove;
directing a light beam towards the solar cell structure through the transparent substrate/superstrate such that substantially only portions of the photoresist deposited between the side walls of the respective grooves are exposed to the light beam;
removing the portions of the photoresist exposed to the light beam;
depositing a conducting layer onto the solar cell structure such that at least portions of the respective side walls of each groove are in electrical contact with one another, and removing the photoresist and the conducting overlayer on the photoresist.

13. The method as claimed in claim 12, wherein a wavelength of the light beam is chosen such that the light beam is absorbed in the solar cell structure.

14. The method as claimed in claim 13, wherein the solar cell structure is silicon based, and the light beam is a UV light beam.

15. The method as claimed in claim 11, wherein the excess dopant atoms required for the formation of the n⁺-type and p⁺-type portions of the electrical contact are provided by a spin-on dopant source.

16. The method as claimed in claim 11, wherein the excess dopant atoms required for the formation of the n⁺-type and p⁺-type portions of the electrical contact are provided by a gas dopant source.

17. The method as claimed in claim 11, comprising the steps of;
forming a first dielectric layer containing n⁺-type or p⁺-type dopant atoms on the solar cell structure;
forming one or more first grooves through the dielectric layer and the entire thickness of the solar cell structure such that side walls of each groove exhibit n⁺-type or p⁺-type doping based on the type of the dopant atoms of the first dielectric layer;
removing the first dielectric layer;
depositing a second dielectric layer that does not contain n-type or p-type dopant atoms;
forming one or more second grooves through the second dielectric layer and the entire thickness of the solar cell structure adjacent to respective first grooves such that one side wall of each first groove is removed and a new side wall is made forming a widened groove;
doping at least a surface region of each new side wall with a polarity opposite to the type of the dopant atoms of the first dielectric layer;
removing the second dielectric layer; and
forming the electrical contact layer over each widened groove such that at least portions of the surface regions of the side walls of the widened groove are in electrical contact with one another.

18. The method as claimed in claim 11, wherein the solar cell structure comprises at least a bottom layer and a top layer of opposite polarity and the bottom layer exhibits a dopant dose that is at least two times higher than the dopant dose of the top layer, the method comprising the steps of
forming one or more first grooves through the entire thickness of the solar cell structure such that side walls of each groove exhibit n⁺-type or p⁺-type doping based on the type of the dopant atoms of the bottom layer;
depositing a dielectric barrier layer that does not contain n-type or p-type dopant atoms;
forming one or more second grooves through the barrier layer and the entire thickness of the solar cell structure adjacent to respective ones of the first grooves such that one side wall of each first groove is removed and a new side wall is formed to form a widened groove;
doping at least a surface region of each new side wall with a polarity opposite to the type of the dopant atoms of the bottom layer;
removing the dielectric barrier layer; and
forming the electrical contact layer over each widened groove such that at least portions of the surface regions of the side walls of the widened groove are in electrical contact with one another.

19. A thin-film solar cell module having top and bottom layers with sheet resistances below 10,000 Ω/sq, the module comprising
a thin-film solar cell structure formed on a foreign insulating substrate or superstrate and comprising at least an n⁺-type layer and a p⁺-type layer, and one or more electrical contacts, each contact being between an n⁺-type layer on one portion of the substrate/superstrate to a p⁺-type layer on an adjacent portion of the substrate/superstrate,
wherein each electrical contact is formed, at least in part, from respective materials of the n⁺-type layer and the p⁺-type layer; and
wherein the materials of the n⁺-type layer and the p⁺-type layer forming part of each electrical contact have undergone a transition into a liquid phase and subsequently into a solid phase during the formation of the electrical contact.
